(19) United States
(12) Patent Application Publication
(10) Pub. No.: US 2026/0227832 A1
(43) Pub. Date: Aug. 6, 2026

(54) SIDE NOZZLE HORIZONTAL WATER-COOLED RADIATOR

(71) Applicant: Dongguan Ice Point Intelligent Technology Co., Ltd, Dongguan (CN)

(72) Inventor: Fengqi Zhang, Dongguan (CN)

(21) Appl. No.: 19/461,700

(22) Filed: Jan. 27, 2026

(30) Foreign Application Priority Data
Jan. 22, 2026 (CN) 202620085984.6

(51) Int. Cl. G06F 1/20; H05K 7/20

(52) U.S. Cl. CPC G06F 1/20; H05K 7/20172; H05K 7/20263; H05K 7/20272; G06F 2200/201

(57) ABSTRACT

A side nozzle horizontal water-cooled radiator comprises a water-cooled bank, a water-cooled pipe, a water pump assembly, a water-cooled block, a PCB mainboard, a water tank structure and a radiating fin assembly; the PCB mainboard, the water pump assembly, the water tank structure and the radiating fin assembly are installed in the water-cooled block from top to bottom; the radiating fin assembly passes through the bottom of the water-cooled block and presses against the external end surface of the CPU; the water tank structure is connected to the water-cooled bank via the water-cooled pipe; the water-cooled pipe is connected to the top of the water-cooled bank; the water-cooled pipe curves from the top of the water-cooled bank to the side thereof; a nozzle structure is arranged on the side of the water-cooled bank; the water-cooled pipe is connected to the water tank structure through the nozzle structure.

### TECHNICAL FIELD

The utility model relates to the technical field of radiator structures, in particular to a side nozzle horizontal water-cooled radiator.

### BACKGROUND ART

As an efficient thermal management solution, water-cooled radiators are widely used in electronic devices such as computers, servers and high-end graphics cards as a replacement for or supplement to traditional air-cooling methods. The basic operating principle is as follows: heat generated by heating elements (such as CPU and GPU) is transferred to the radiator by a circulating liquid (usually water or specialized coolant), after which a fan dissipates the heat into the air. A typical water-cooling system mainly consists of a heat-absorbing block (water-cooled block), a water pump, a water-cooled bank, a fan, a water-cooled pipe and connectors.

In the prior art, most water-cooled radiators share a common structural issue: the connection and routing of the water-cooling pipe occupy significant space, and the assembly convenience requires improvement.

In traditional water-cooled radiators, the inlet and return nozzles are typically positioned on the front side (usually the side where the fan is installed) or at the end of the water-cooled bank. After exiting the nozzles, the water-cooled pipe often needs to cross the front or side space of the water-cooled bank to be connected to the water-cooled block and the water pump. This layout causes water-cooled pipes to wind inside the case, occupying valuable internal space, and particularly interfering with airduct planning or areas near the mainboard and the memory. Moreover, disorganized pipes block other hardware components, compromise overall aesthetics, and potentially interfere with subsequent maintenance and upgrade operations. This issue is particularly pronounced in systems (such as ITX cases, all-in-one machines, or certain embedded devices) that prioritize compact layouts and miniaturized designs.

Furthermore, current designs are inconvenient to assemble and exhibit low efficiency. Since the nozzles are positioned on the front or ends of the water-cooled bank, it is necessary to avoid the fan, the mainboard radiating fins, the memory bank and other obstacles when connecting and fixing the water-cooled pipes particularly in the space-constrained cases during installation. The limited operation space makes the assembly process cumbersome and demands greater technical skill from the installer.

There is a need for a new side nozzle horizontal water-cooled radiator that can address the issues mentioned above.

### SUMMARY OF THE UTILITY MODEL

The utility model provides a side nozzle horizontal water-cooled radiator that addresses the issues of inconvenient assembly of nozzles and water-cooled pipes and enhances the performance shortcomings of the existing water-cooled radiators through technical improvements.

To achieve the above-mentioned objectives, the utility model adopts the following technical solution:

a side nozzle horizontal water-cooled radiator, comprising a water-cooled bank, a water-cooled pipe, a water pump assembly, a water-cooled block, a PCB mainboard, a water tank structure and a radiating fin assembly; the PCB mainboard, the water pump assembly, the water tank structure and the radiating fin assembly are installed in the water-cooled block from top to bottom; the radiating fin assembly passes through the bottom of the water-cooled block and presses against the external end surface of a CPU; the water tank structure is connected to the water-cooled bank positioned outside the water-cooled block via the water-cooled pipe; the water-cooled pipe is connected to the top of the water-cooled bank; the water-cooled pipe curves from the top of the water-cooled bank to the side thereof; a nozzle structure is arranged on the side of the water-cooled bank; the water-cooled pipe is connected to the water tank structure through the nozzle structure.

Preferably, the water-cooled pipe comprises an inlet pipe and an outlet pipe, while the nozzle structure comprises an inlet nozzle and an outlet nozzle; the inlet nozzle and the outlet nozzle are fixedly installed on one side of the water-cooled block and are connected to the water tank structure; the inlet pipe connects the inlet nozzle to the water-cooled bank, while the outlet pipe connects the outlet nozzle to the water-cooled bank.

Preferably, a top protective housing is fixedly arranged at the top of the water-cooled bank, while a side protective housing is fixedly arranged on the side of the water-cooled bank; the water-cooled pipe passes through both the side protective housing and the top protective housing before connecting to the top joint of the water-cooled bank.

Preferably, the water tank structure comprises a main bottom housing, a water storage tank, a heat sink, water baffles and a waterway cover plate; the water baffles are installed at intervals between the main bottom housing and the radiating fin assembly; the water storage tank is formed between the water baffle and the cavity of the main bottom housing; the heat sink is formed between the water baffle and the radiating fin assembly; the water pump assembly, which conveys cooling liquid, is installed in the water storage tank; a water outlet is provided on the inner wall of the water storage tank and is connected to the outlet nozzle; a water inlet is provided on the main bottom housing, connected to the inlet nozzle, passes through the water baffles and is connected to the heat sink; the waterway cover plate is installed on the side of the water baffles opposite the radiating fin assembly; a cover plate hole is provided at the center of the waterway cover plate; a perforated hole is provided at the center of the water baffle; the cooling liquid in the heat sink flows sequentially into the water storage tank through the cover plate hole and the perforated hole.

Preferably, the water baffle is provided with an opening that matches the shape of the water inlet and is positioned in alignment with the water inlet.

Preferably, a sealing ring groove is circumferentially arranged on the bottom surface of the main bottom housing, and a waterway sealing ring is installed in the sealing ring groove, abutting both the main base housing and the radiating fin assembly.

Preferably, a micro waterway is fixedly arranged on the radiating fin assembly; the waterway cover plate abuts against the micro waterway; the cover plate hole is positioned directly opposite the center of the micro waterway, and arc-shaped water collecting grooves extend from the cover plate hole and are positioned towards both sides of the waterway cover plate.

Preferably, the water pump assembly comprises a drive motor and an impeller; the impeller is rotatably installed inside the water storage tank; the drive motor drives the rotation of the impeller and is electrically connected to the PCB mainboard; the water outlet is positioned along the tangential direction of the impeller’s rotation.

Preferably, an LED assembly is installed on the PCB mainboard and is electrically connected to the PCB mainboard.

Preferably, a fan assembly is installed on the water-cooled bank, with the air inlet of the fan assembly facing directly opposite the water-cooled bank.

The utility model has the following beneficial effects:

In this application, the water-cooled pipe is closely attached to the side of the water-cooled bank, occupying minimal additional three-dimensional space in front of or around the water-cooled bank, greatly freeing up internal case space, which is particularly beneficial for compact designs and multi-hardware system layouts, resulting in improved space utilization.

In this application, the side nozzle design positions the pipe connection point at the edge of the water-cooled bank, providing a broader operation field of view, facilitating access and tightening of the joint, significantly reducing the installation difficulty in confined spaces and improving the assembly efficiency.

This design prevents potential interference of the pipe with airflow on the front of the water-cooled bank, ensuring efficient cooling. Meanwhile, the organized side-pipe layout reduces the likelihood of interference with other components inside the case, enhancing system compatibility and reliability. Furthermore, the water-cooled pipe can be arranged in a directed and organized manner along the side of the water-cooled bank, preventing messy and disordered pipe routes, maintaining a tidy case interior, minimizing obstruction with other hardware and lighting effects, and improving the overall aesthetic appeal.

### BRIEF DESCRIPTION OF THE DRAWINGS

FIG. 1 is a stereoscopic structural diagram of the utility model;

FIG. 2 is a schematic diagram of the installation structure of the water-cooled bank of the utility model;

FIG. 3 is an exploded view of the water-cooled block and water tank structure of the utility model;

FIG. 4 is an exploded view of the water tank structure of the utility model;

FIG. 5 is a schematic diagram of the installation structure of the water tank structure of the utility model;

FIG. 6 is a sectional structural diagram of the water tank structure and the radiating fin assembly of the utility model;

Reference signs: Water-cooled bank 1, top protective housing 11, side protective housing 12, fan assembly 13, water-cooled pipe 2, inlet pipe 21, outlet pipe 22, water pump assembly 3, drive motor 31, impeller 32, water-cooled block 4, PCB mainboard 5, LED assembly 51, water tank structure 6, main bottom housing 61, water inlet 611, sealing ring groove 612, water storage groove 62, water outlet 6, heat sink 63, water baffle 64, perforated hole 641, waterway cover plate 65, cover plate hole 651, arc-shaped water collecting groove 652, radiating fin assembly 7, micro waterway 71, nozzle structure 8, inlet nozzle 81, outlet nozzle 82, waterway sealing ring 9.

### DETAILED DESCRIPTION OF THE UTILITY MODEL

The utility model is described in detail below with reference to the drawings and embodiments.

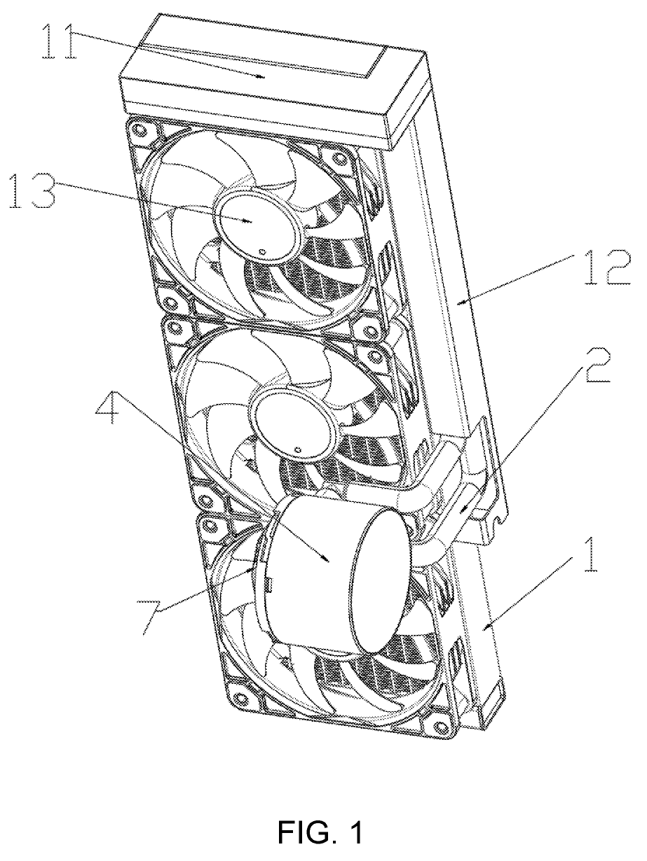

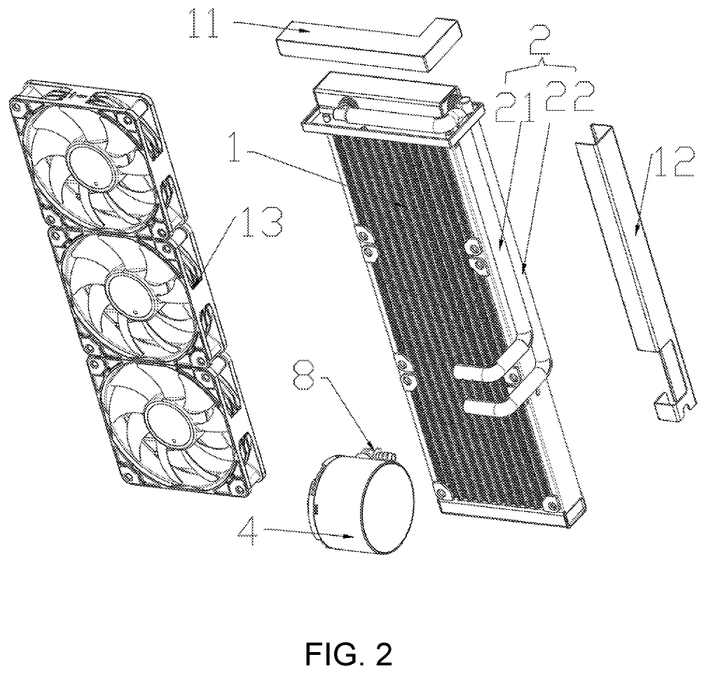

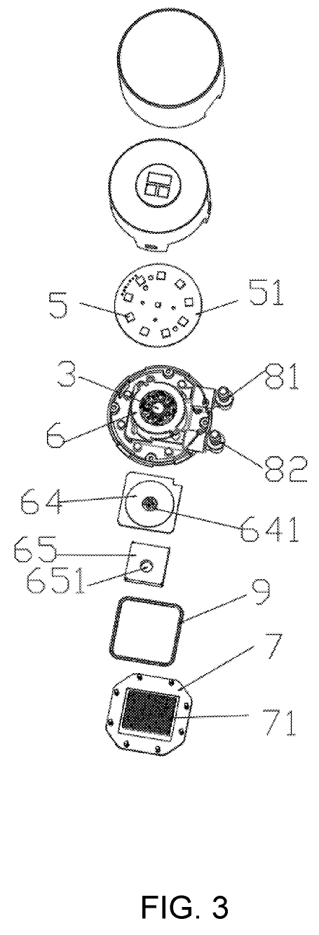

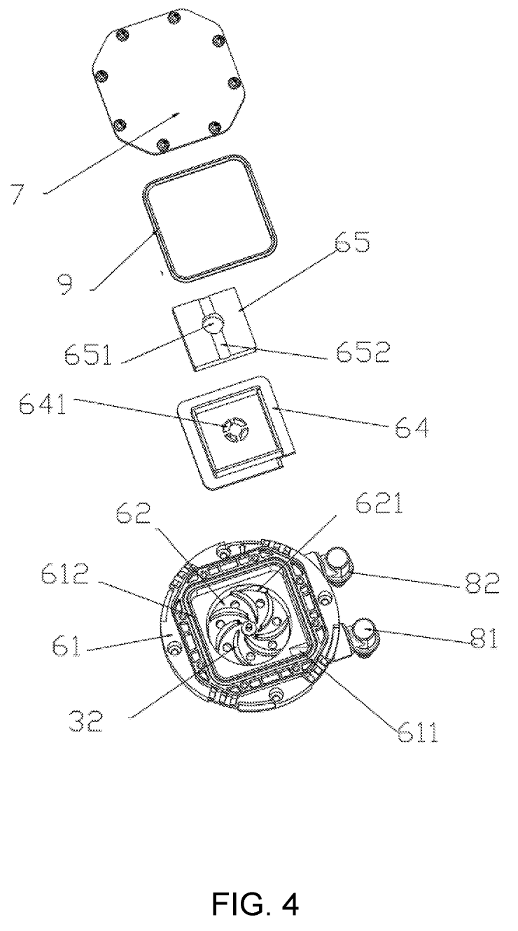

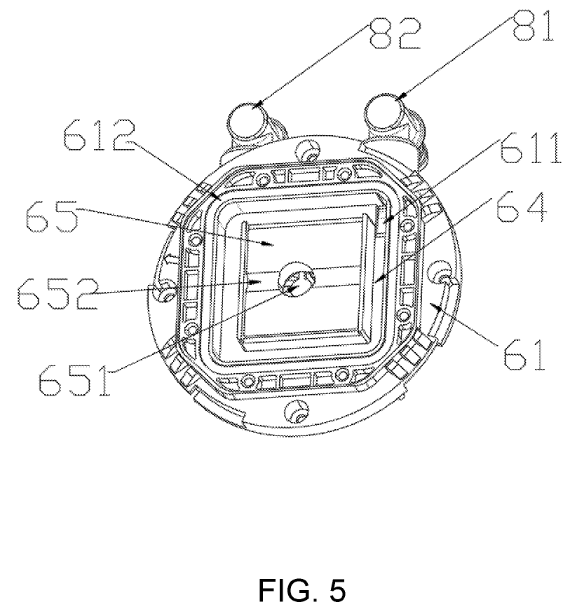

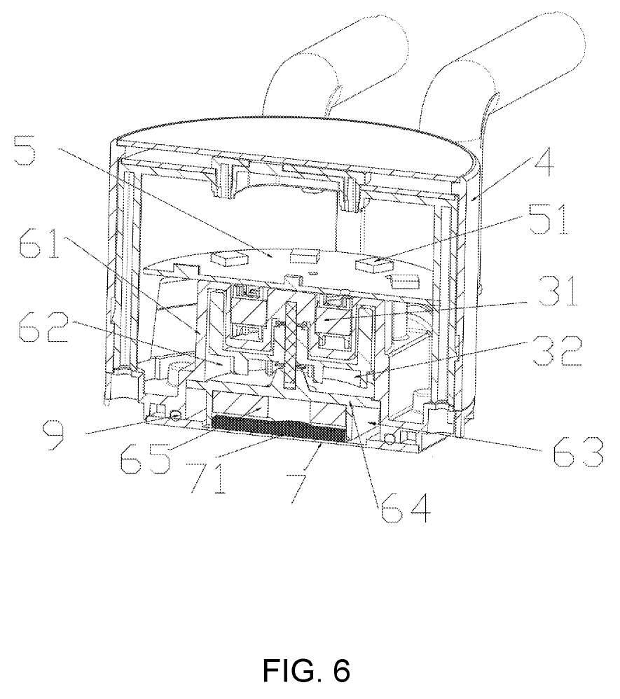

As shown in FIG. 1-6, the utility model provides a side nozzle horizontal water-cooled radiator, comprising a water-cooled bank 1, a water-cooled pipe 2, a water pump assembly 3, a water-cooled block 4, a PCB mainboard 5, a water tank structure 6 and a radiating fin assembly 7; the PCB mainboard 5, the water pump assembly 3, the water tank structure 6 and the radiating fin assembly 7 are installed in the water-cooled block 4 from top to bottom; the radiating fin assembly 7 passes through the bottom of the water-cooled block 4 and presses against the external end surface of a CPU; the water tank structure 6 is connected to the water-cooled bank 1 arranged outside the water-cooling block 4 through the water-cooled pipe 2; the water-cooled pipe 2 is connected to the top of the water-cooled bank 1; the water-cooled pipe 2 curves from the top of the water-cooled bank 1 to the side thereof; a nozzle structure 8 is arranged on the side of the water-cooled bank 1; the water-cooled pipe 2 is connected to the water tank structure 6 through the nozzle structure 8.

Further, to enable circulation of the cooling liquid, the water-cooled pipe 2 comprises an inlet pipe 21 and an outlet pipe 22; the nozzle structure 8 comprises an inlet nozzle 81 and an outlet nozzle 82; the inlet nozzle 81 and the outlet nozzle 82 are fixedly installed on one side of the water-cooled block 4 and are connected to the water tank structure 6; the inlet pipe 21 connects the inlet nozzle 81 to the water-cooled bank 1, while the outlet pipe 22 connects the outlet nozzle 82 to the water-cooled bank 1. The inlet pipe 21 and the outlet pipe 22 extend from the top joint of the water-cooled bank 1 and along the side surface of the water-cooled bank 1 until the inlet pipe 21 and the outlet pipe 22 are connected to the inlet nozzle 81 and the outlet nozzle 82.

Further, a top protective housing 11 is fixedly arranged at the top of the water-cooled bank 1, covering the upper portion of the water-cooling pipe 2; a side protective housing 12 is fixedly arranged on the side of the water-cooled bank 1; the water-cooled pipe 2 passes through the side protective housing 12 and the top protective housing 11 before connecting to the top joint of the water-cooled bank 1. The top protective housing 11 and the side protective housing 12 can be fixed to the water-cooled bank 1 using fasteners or screws.

Further, to facilitate the entry of cooling liquid into the water tank structure 6 for circulation, the water tank structure 6 comprises a main bottom housing 61, a water storage tank 62, a heat sink 63, water baffles 64 and a waterway cover plate 65; the water baffles 64 are installed at intervals between the main bottom housing 61 and the radiating fin assembly 7; the water storage tank 62 is formed between the water baffle 64 and the cavity of the main bottom housing 61; the heat sink 63 is formed between the water baffle 64 and the radiating fin assembly 7; the water pump assembly 3, which conveys the cooling liquid, is installed in the water storage tank 62; a water outlet 621 is provided on the inner wall of the water storage tank 62 and is connected to the outlet nozzle 82; a water inlet 611 is provided on the main bottom housing 61, is connected to the inlet nozzle 81, passes through the water baffles 64 and is connected to the heat sink 63; the waterway cover plate 65 is installed on the side of the water baffles 64 opposite the radiating fin assembly 7; a cover plate hole 651 is provided at the center of the waterway cover plate 65; a perforated hole 641 is provided at the center of the water baffle 64; the cooling liquid in the heat sink 63 flows sequentially through the cover plate hole 651 and the perforated hole 641 into the water storage tank 62.

Further, the water baffle 64 is provided with an opening that matches the shape of the water inlet 611 and is positioned in alignment with the water inlet 611.

Further, a sealing ring groove 612 is circumferentially arranged on the bottom surface of the main bottom housing 61, and a waterway sealing ring 9 is installed in the sealing ring groove 612, abutting both the main base housing 61 and the radiating fin assembly 7.

Further, a micro waterway 71 is fixedly arranged on the radiating fin assembly 7; the waterway cover plate 65 abuts against the micro waterway 71; the cover plate hole 651 is positioned directly opposite the center of the micro waterway 71; arc-shaped water collecting grooves 652 extend from the cover plate hole 651 and are positioned towards both sides of the waterway cover plate 65. The arc-shaped water collecting grooves 652 collect the cooling liquid from the micro waterway 71, facilitating the flow of the cooling liquid towards the water storage tank 62 through the cover plate hole 651.

Further, the water pump assembly 3 comprises a drive motor 31 and an impeller 32; the impeller 32 is rotatably installed inside the water storage tank 62; the drive motor 31 drives the rotation of the impeller 32 and is electrically connected to the PCB mainboard 5; the water outlet 621 is positioned along the tangential direction of rotation of the impeller 32. The drive motor 31 drives the impeller 32 to rotate and throw the cooling liquid from the water storage tank 62 into the water outlet 621, thereby facilitating pumping from the outlet nozzle 82.

Further, to enhance the lighting effects and expand functionality, an LED assembly 51 is installed on the PCB mainboard 5 and is electrically connected to the PCB mainboard 5.

Further, to enhance heat dissipation, a fan assembly 13 is installed on the water-cooled bank 1, and the air inlet of the fan assembly 13 is directly opposite the water-cooled bank 1. The fan assembly 13 blows air to cool the water-cooled bank 1.

Operating principle: Driven by the impeller 32 of the water pump assembly 3, the cooling liquid flows from the water outlet 621 of the water storage tank 62 into the outlet nozzle 82, and then enters the internal flow channel of the water-cooled bank 1 through the outlet pipe 22. The fan assembly 13 blows air to cool the water-cooled bank 1. The cooled liquid flows from the water-cooled bank 1 into the outlet pipe 22, and then enters the heat sink 63 of the water tank structure 6 through the inlet nozzle 81. The cooling liquid passes through the micro waterway 71 of the radiating fin assembly 7, absorbs heat dissipated from the CPU, gathers at the central region, flows sequentially through the cover plate hole 651 of the waterway cover plate 65 and the perforated hole 641 of the water baffle 64, and enters the water storage tank 62, thereby completing the circulation cycle.

In this application, the water-cooled pipe 2 can be closely attached to the side of the water-cooled bank 1, occupying minimal additional three-dimensional space in front of or around the water-cooled bank 1, greatly freeing up internal case space, which is particularly beneficial for compact designs and multi-hardware system layouts, resulting in improved space utilization.

In this application, the side nozzle design positions the pipe connection point at the edge of the water-cooled bank 1, providing a broader operation field of view, facilitating access and tightening of the joint, significantly reducing the installation difficulty in confined spaces and improving assembly efficiency.

This application prevents potential interference of the pipe with the airflow in front of the water-cooled bank 1, ensuring efficient cooling. Meanwhile, the organized side pipe layout reduces the likelihood of interference with other components inside the case, enhancing system compatibility and reliability. Furthermore, the water-cooled pipe 2 can be arranged in a directed and organized manner along the side of the water-cooled bank 1, preventing messy and disordered pipe route, maintaining a tidy case interior, minimizing obstruction of other hardware and lighting effects, and improving the overall aesthetic appeal.

Finally, it should be noted that the above embodiments are provided only to illustrate the technical solutions of the utility model and are not intended to limit them. Although the utility model has been described in detail with reference to the preferred embodiments, those skilled in the art will understand that modifications or equivalent replacements to the technical solutions of the utility model may be made without departing from the purpose and scope of the technical solutions of the utility model. Any such modifications or equivalent replacements should be covered within the scope of the claims of the utility model.

All standard parts used in the utility model are available for purchase on the market. Special-shaped parts can be customized according to the description and the drawings. The parts are connected using conventional methods such as bolts, rivets, and welding, which are mature in the prior art. The machinery, parts and equipment are of conventional models from the prior art, and the circuit connections follow conventional methods from the prior art. These details will not be further elaborated here.

In the description of the utility model, unless otherwise explicitly specified and defined, the terms “installed”, “connected”, “coupled” and “fixed” should be interpreted in a broad sense. For example, connections may be fixed, detachable or integral connections; they may be mechanical or electrical connections; they may be direct connections or achieved through an intermediate medium; they may be internal connections or interaction relationships between two elements. Those skilled in the art will understand the specific meanings of these terms in the context of the utility model according to the relevant circumstances.

1. A side nozzle horizontal water-cooled radiator, comprising a water-cooled bank, a water-cooled pipe, a water pump assembly, a water-cooled block, a PCB mainboard, a water tank structure and a radiating fin assembly; the PCB mainboard, the water pump assembly, the water tank structure and the radiating fin assembly are installed in the water-cooled block from top to bottom; the radiating fin assembly passes through the bottom of the water-cooled block and presses against the external end surface of a CPU; the water tank structure is connected to the water-cooled bank positioned outside the water-cooled block via the water-cooled pipe; the water-cooled pipe is connected to the top of the water-cooled bank; the water-cooled pipe curves from the top of the water-cooled bank to the side thereof; a nozzle structure is arranged on the side of the water-cooled bank; the water-cooled pipe is connected to the water tank structure through the nozzle structure.

2. The side nozzle horizontal water-cooled radiator according to claim 1, wherein the water-cooled pipe comprises an inlet pipe and an outlet pipe, while the nozzle structure comprises an inlet nozzle and an outlet nozzle; the inlet nozzle and the outlet nozzle are fixedly installed on one side of the water-cooled block and are connected to the water tank structure; the inlet pipe connects the inlet nozzle to the water-cooled bank, while the outlet pipe connects the outlet nozzle to the water-cooled bank.

3. The side nozzle horizontal water-cooled radiator according to claim 1, wherein a top protective housing is fixedly arranged at the top of the water-cooled bank, a side protective housing is fixedly arranged on the side of the water-cooled bank, and the water-cooled pipe passes through both the side protective housing and the top protective housing before connecting to the top joint of the water-cooled bank.

4. The side nozzle horizontal water-cooled radiator according to claim 1, wherein the water tank structure comprises a main bottom housing, a water storage tank, a heat sink, water baffles and a waterway cover plate; the water baffles are installed at intervals between the main bottom housing and the radiating fin assembly; the water storage tank is formed between the water baffle and the cavity of the main bottom housing; the heat sink is formed between the water baffle and the radiating fin assembly; the water pump assembly, which conveys the cooling liquid, is installed in the water storage tank; a water outlet is provided on the inner wall of the water storage tank and is connected to the outlet nozzle; a water inlet is provided on the main bottom housing, is connected to the inlet nozzle, passes through the water baffles and is connected to the heat sink; the waterway cover plate is installed on the side of the water baffles opposite the radiating fin assembly; a cover plate hole is provided at the center of the waterway cover plate; a perforated hole is provided at the center of the water baffle; the cooling liquid in the heat sink flows sequentially through the cover plate hole and the perforated hole into the water storage tank.

5. The side nozzle horizontal water-cooled radiator according to claim 4, wherein the water baffle is provided with an opening that matches the shape of the water inlet and is positioned in alignment with the water inlet.

6. The side nozzle horizontal water-cooled radiator according to claim 4, wherein a sealing ring groove is circumferentially arranged on the bottom surface of the main bottom housing, and a waterway sealing ring is installed in the sealing ring groove, abutting both the main base housing and the radiating fin assembly.

7. The side nozzle horizontal water-cooled radiator according to claim 4, wherein a micro waterway is fixedly arranged on the radiating fin assembly, the waterway cover plate abuts against the micro waterway, the cover plate hole is positioned directly opposite the center of the micro waterway, and arc-shaped water collecting grooves extend from the cover plate hole and are positioned towards both sides of the waterway cover plate.

8. The side nozzle horizontal water-cooled radiator according to claim 4, wherein the water pump assembly comprises a drive motor and an impeller; the impeller is rotatably installed inside the water storage tank; the drive motor drives the rotation of the impeller and is electrically connected to the PCB mainboard, and the water outlet is positioned along the tangential direction of the impeller’s rotation.

9. The side nozzle horizontal water-cooled radiator according to claim 1, wherein an LED assembly is installed on the PCB mainboard.

10. The side nozzle horizontal water-cooled radiator according to claim 1, wherein a fan assembly is installed on the water-cooled bank, and the air inlet of the fan assembly is directly opposite the water-cooled bank.
